(19) United States
(12) Patent Application Publication
(10) Pub. No.: US 2025/0147245 A1
(43) Pub. Date: May 8, 2025

(54) PACKAGE ASSEMBLY AND MANUFACTURING METHOD THEREOF

(71) Applicant: Taiwan Semiconductor Manufacturing Company, Ltd., Hsinchu (TW)

(72) Inventors: Wen-Chih Lin, Hsinchu (TW); Hsuan-Ting Kuo, Taichung City (TW); Cheng-Yu Kuo, Kaohsiung City (TW); Yen-Hung Chen, Hsinchu City (TW); Chia-Shen Cheng, Hsinchu County (TW); Chao-Wei Li, Hsinchu City (TW); Ching-Hua Hsieh, Hsinchu (TW); Wen-Chih Chiou, Miaoli County (TW)

(73) Assignee: Taiwan Semiconductor Manufacturing Company, Ltd., Hsinchu (TW)

(21) Appl. No.: 18/503,189

(22) Filed: Nov. 7, 2023

(51) Int. Cl. G02B 6/42; H01L 23/00; H01L 25/16

(52) U.S. Cl. CPC G02B 6/4214; H01L 25/167; H01L 24/08; H01L 24/16; H01L 2224/08145; H01L 2224/16145

(57) ABSTRACT

A package assembly and a manufacturing method thereof are provided. The package assembly includes a photonic integrated circuit component, an electric integrated circuit component, a lens and an optical signal port. The photonic integrated circuit component comprises an optical input/output portion configured to transmit and receive optical signal. The electric integrated circuit component is electrically connected to the photonic integrated circuit component. The lens is disposed on a sidewall of the photonic integrated circuit component. The optical signal port is optically coupled to the optical input/output portion.

### BACKGROUND

Currently, semiconductor packages including both photonic dies (known as P-dies) and electronic dies (known as E-dies) are becoming increasingly popular for their compactness. In addition, due to the widely use of optical fiber-related applications for signal transmission, optical signaling and processing have been used in more applications. Although existing methods of fabricating the semiconductor packages have been generally adequate for their intended purposes, they have not been entirely satisfactory in all respects. For example, challenges rise to improve the coupling tolerance between the fiber and the waveguide.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A through 1K are cross-sectional views illustrating a process flow for fabricating a package assembly in accordance with some embodiments of the present disclosure.

FIG. 2 is a schematic top view of the fibers in accordance with some embodiments of the present disclosure.

FIG. 3 is a schematic cross-sectional view of a package assembly in accordance with some alternative embodiments of the present disclosure.

FIG. 4 is a schematic cross-sectional view of a package assembly in accordance with some alternative embodiments of the present disclosure.

FIG. 5 is a schematic cross-sectional view of a package assembly in accordance with some alternative embodiments of the present disclosure.

FIG. 6 is a schematic cross-sectional view of a package assembly in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments of the present disclosure are discussed in the context of semiconductor manufacturing, and in particular, in the context of forming a package assembly, wherein the package assembly includes an optical engine having a photonic integrated circuit component and an electric integrated circuit component, a lens disposed on a sidewall of the photonic integrated circuit component, and an optical signal port optically coupled to the photonic integrated circuit component. Some variations of embodiments are discussed and the intermediate stages of forming the package assembly are illustrated in accordance with some embodiments. It should be appreciated that the illustration throughout the drawings are schematic and not in scale.

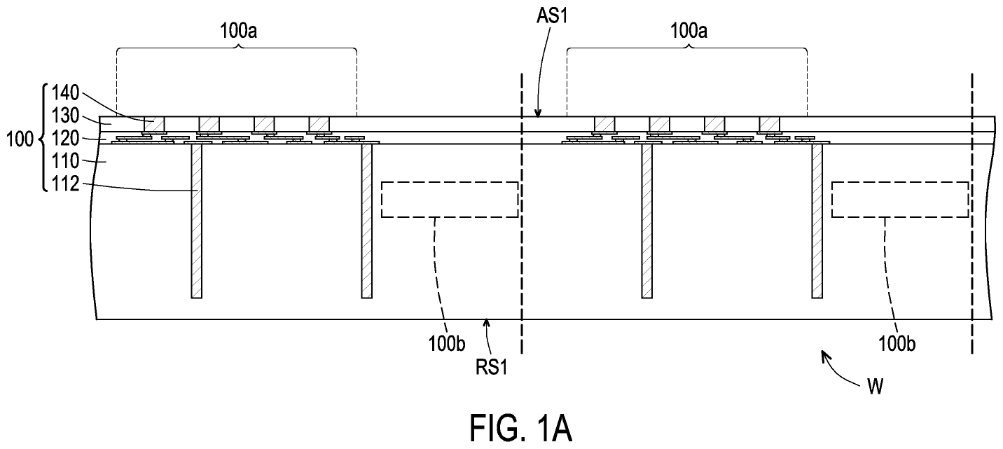

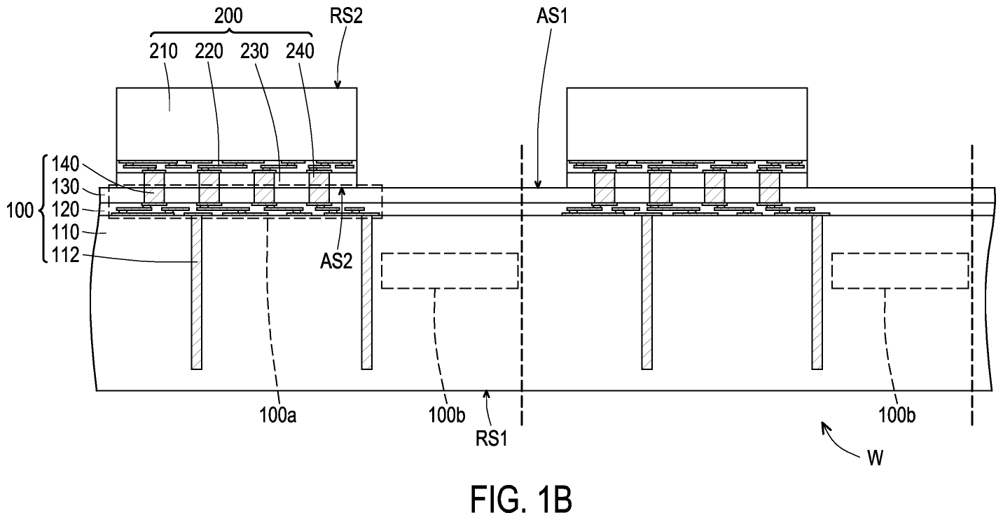

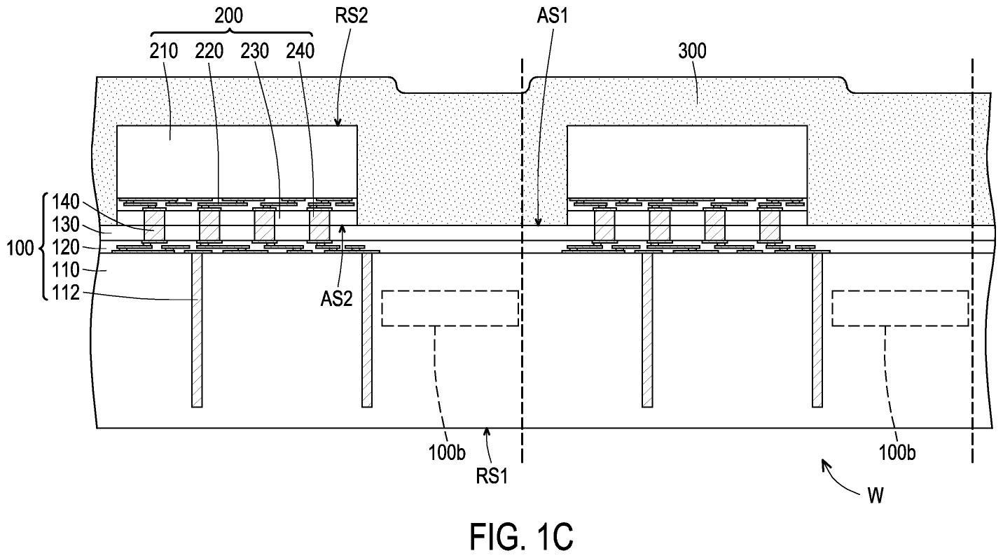

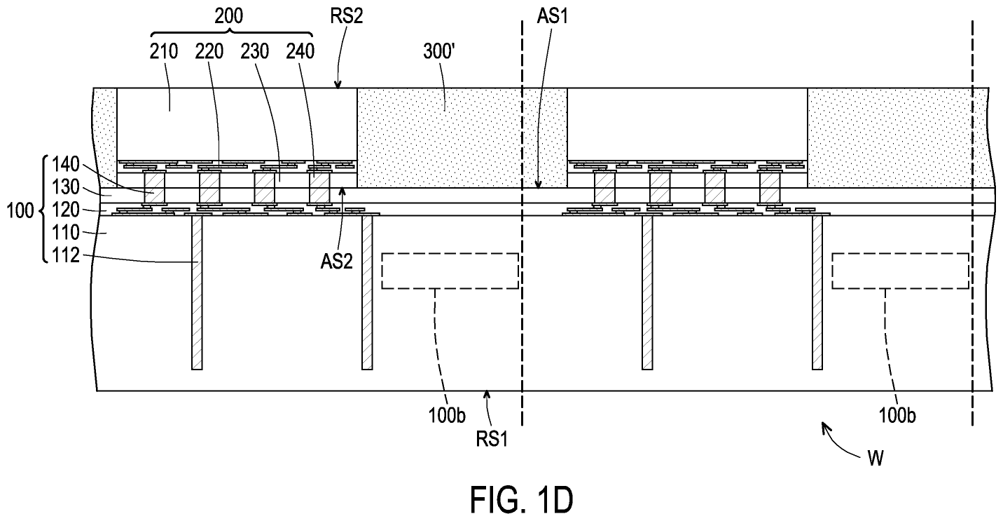

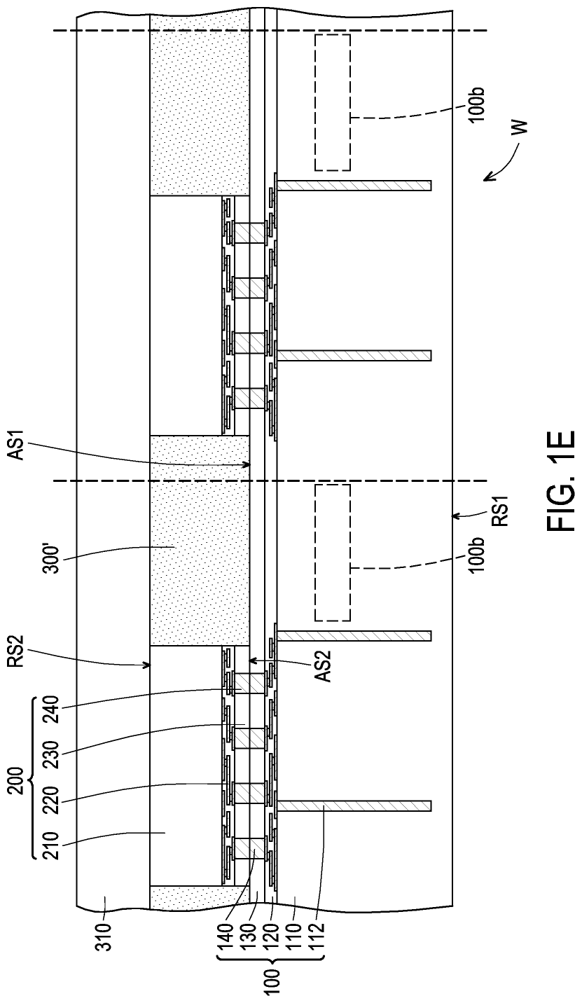

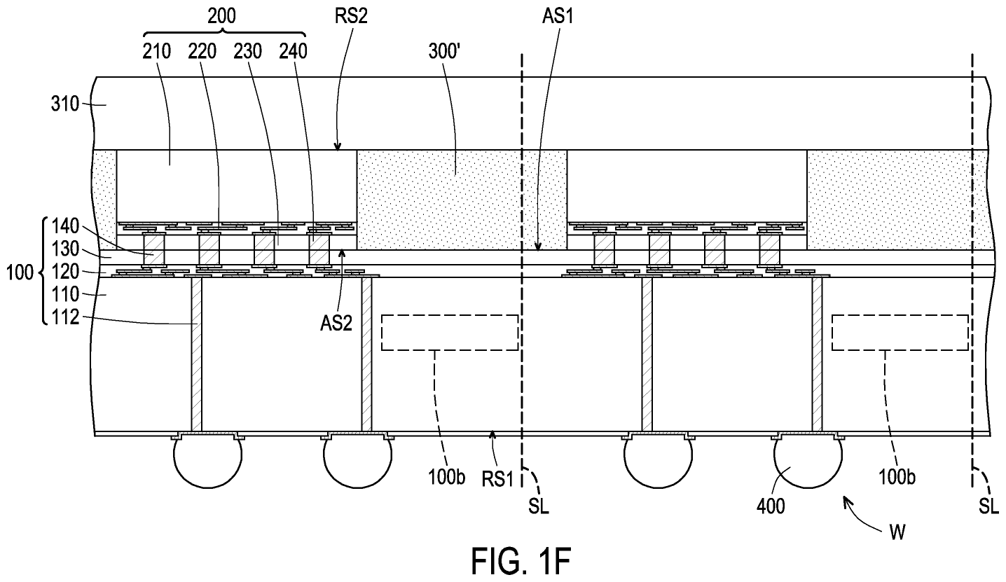

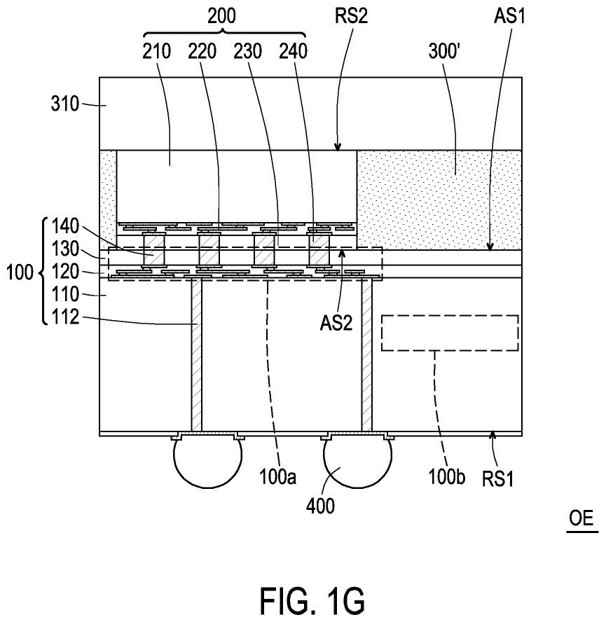

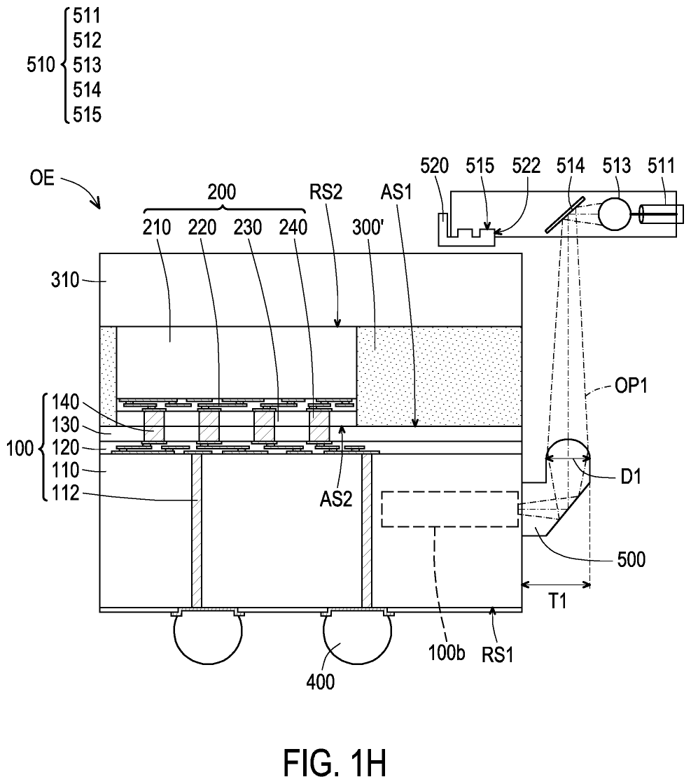

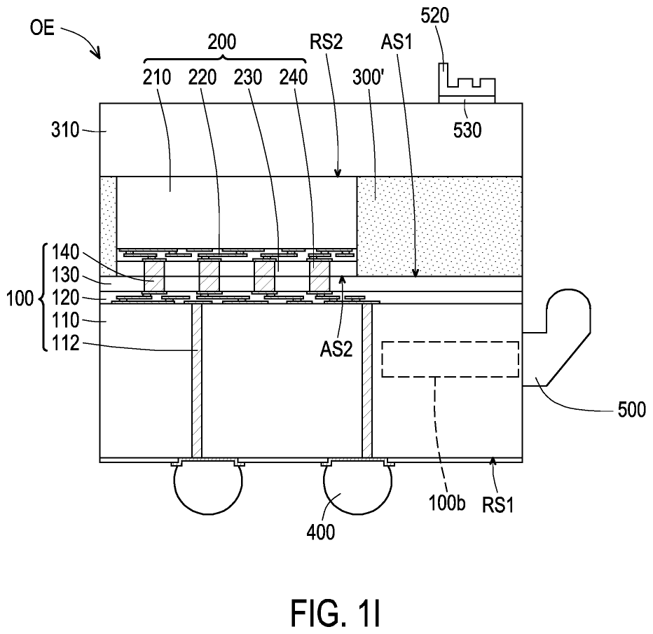

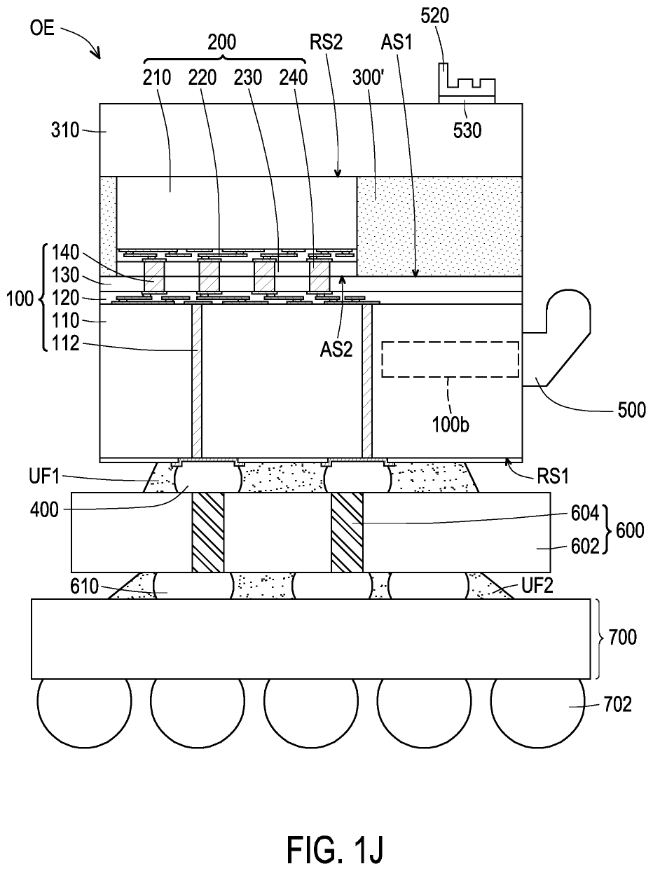

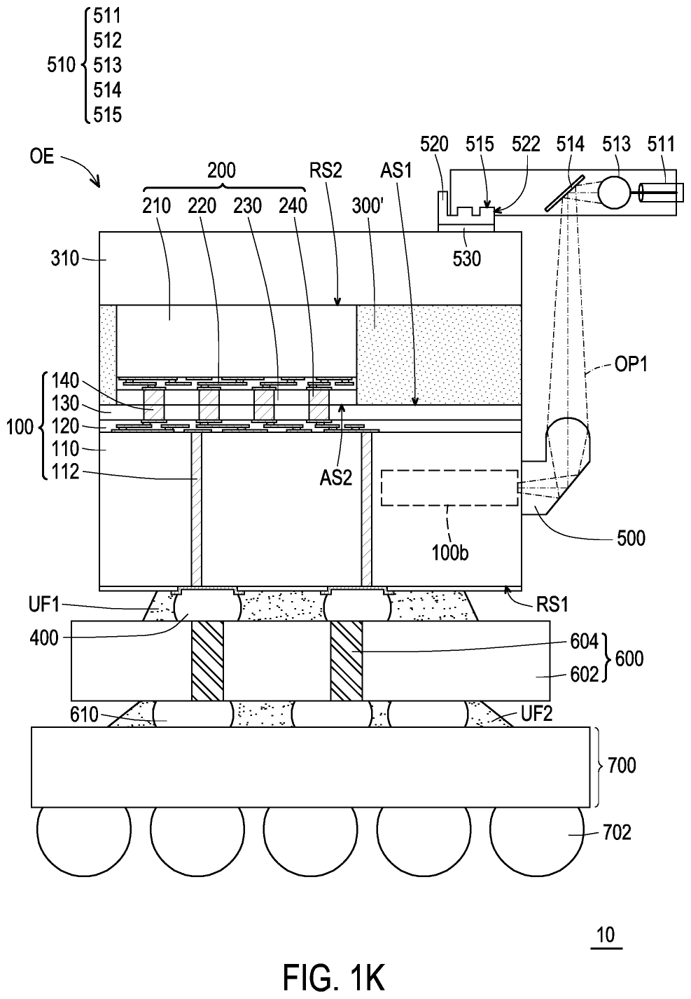

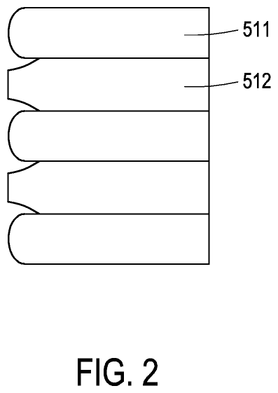

FIGS. 1A through 1K are cross-sectional views illustrating a process flow for fabricating a package assembly 10 in accordance with some embodiments of the present disclosure. FIG. 2 is a schematic top view of the fibers in accordance with some embodiments of the present disclosure.

Referring to FIG. 1A, a photonic wafer W including a plurality of photonic integrated circuit components 100 therein is provided. The photonic integrated circuit components 100 are arranged in array and physically connected to one another. Each of the photonic integrated circuit components 100 includes an electrical bonding portion 100a and at least one optical input/output portion 100b configured to transmit and receive optical signal. The optical signal is, for example, pulsed light, light with continuous wave (CW) or the combinations thereof. In some embodiments, the electrical bonding portions 100a of the photonic integrated circuit components 100 may include semiconductor devices (e.g., transistors, capacitors and so on), wirings or conductors for electrical connection, and the optical input/output portions 100b of the photonic integrated circuit components 100 may include semiconductor devices and optical devices for processing the optical signal. For example, the semiconductor devices formed in the optical input/output portions 100b may include transistors, capacitors, photodiodes or the combination thereof, and the optical devices formed in the optical input/output portions 100b may include waveguides, modulators, grating coupler, edge coupler, filters or the combination thereof. As shown in FIG. 1A, the photonic wafer W may include a first active surface AS1 and a first rear surface RS1 opposite to the first active surface AS1, wherein the electrical bonding portions 100a is located at the first active surface AS1 of the photonic wafer W.

The photonic wafer W may include a first semiconductor substrate 110 having a plurality of semiconductor devices and optical devices formed therein; a first interconnection structure 120 disposed on the first semiconductor substrate 110; a first dielectric layer 130 covering the first interconnection structure 120; and a plurality of first conductors 140 surrounded by the first dielectric layer 130. In some embodiments, the first conductors 140 are embedded in the first dielectric layer 130. The first conductors 140 are electrically connected to the first semiconductor substrate 110 through the first interconnection structure 120. In some embodiments, the material of the first conductors 140 may be copper (Cu) or other suitable metallic material while the material of the first dielectric layer 130 may be silicon oxide (SiOₓ, where x>0), silicon nitride (SiNₓ, where x>0), silicon oxynitirde (SiOₓN_{y}, where x>0 and y>0) or other suitable dielectric material.

The first dielectric layer 130 may be formed by depositing a dielectric material layer on the first interconnection structure 120 and patterning the dielectric material layer to form a plurality of openings in the dielectric material layer. The openings formed in the first dielectric layer 130 expose portions of the first interconnection structure 120. After the first dielectric layer 130 is patterned, a conductive material layer may be deposited on the first dielectric layer 130 and the portions of the first interconnection structure 120 exposed by the openings of the first dielectric layer 130. Then, a polishing process (e.g., a chemical mechanical polishing process) is performed to partially remove the conductive material layer until the top surface of the first dielectric layer 130 is exposed. After performing the polishing process, the first conductors 140 are formed in the openings of the first dielectric layer 130. As shown in FIG. 1A, the top surfaces of the first conductors 140 and the top surface of the first dielectric layer 130 are at substantially the same level so as to provide an appropriate surface for bonding, for example, dielectric-to-dielectric bonding, conductor-to-conductor bonding, or combination thereof. Herein, when surfaces or elements are described as “at substantially the same level”, the surfaces or elements are formed at substantially the same height. In other words, the top surfaces of the first conductors 140 and the top surface of the first dielectric layer 130 at substantially the same level are substantially coplanar.

As shown in FIG. 1A, the photonic wafer W may further include a plurality of through semiconductor vias (TSV) 112 embedded in the first semiconductor substrate 110. The through semiconductor vias 112 are electrically connected to the first interconnection structure 120 and extend downward into the first semiconductor substrate 110 without penetrating the first semiconductor substrate 110. In other words, the through semiconductor vias 112 embedded in the first semiconductor substrate 110 are not exposed at the first rear surface RS1 of the photonic wafer W.

Referring to FIG. 1B, a plurality of electric integrated circuit components 200 are provided. Each of the electric integrated circuit components 200 may include a second semiconductor substrate 210 having a plurality of semiconductor devices formed therein; a second interconnection structure 220 disposed on the second semiconductor substrate 210; a second dielectric layer 230 covering the second interconnection structure 220; and a plurality of second conductors 240 surrounded by the second dielectric layer 230. In some embodiments, the second conductors 240 are embedded in the second dielectric layer 230. The second conductors 240 are electrically connected to the second semiconductor substrate 210 through the second interconnection structure 220. In some embodiments, the material of the second conductors 240 may be copper (Cu) or other suitable metallic material while the material of the second dielectric layer 230 may be silicon oxide (SiOₓ, where x>0), silicon nitride (SiNₓ, where x>0), silicon oxynitirde (SiOₓN_{y}, where x>0 and y>0) or other suitable dielectric material.

As shown in FIG. 1B, each of the electric integrated circuit components 200 may include a second active surface AS2 and a second rear surface RS2 opposite to the second active surface AS2. The electric integrated circuit components 200 may be picked-up and placed onto the first active surface AS1 of the photonic wafer W such that the first active surface AS1 of the photonic wafer W is in contact with the second active surfaces AS2 of the electric integrated circuit components 200, and the second conductors 240 of the electric integrated circuit components 200 are substantially aligned and in contact with the first conductors 140 of the photonic integrated circuit components 100 in the photonic wafer W. The electric integrated circuit components 200 are picked-up and placed to cover the electrical bonding portions 100a of photonic integrated circuit components 100. In some embodiments, each of the optical input/output portions 100b of the photonic integrated circuit components 100 is not covered by the corresponding electric integrated circuit component 200. However, the disclosure is not limited thereto. In some alternative embodiments, each of the optical input/output portions 100b of the photonic integrated circuit components 100 is partially covered by the corresponding electric integrated circuit components 200. In some embodiments, since the photonic integrated circuit components 100 are arranged in array in the photonic wafer W, the electric integrated circuit components 200 placed on the photonic wafer W are also arranged in array.

In some embodiments, to facilitate the chip-to-wafer bonding between the electric integrated circuit components 200 and the photonic wafer W, surface preparation for bonding surfaces (i.e., the first active surface AS1 and the second active surface AS2) of the photonic wafer W and the electric integrated circuit components 200 may be performed. The surface preparation may include surface cleaning and activation, for example. Surface cleaning may be performed on the first active surface AS1 of the photonic wafer W and the second active surfaces AS2 of the electric integrated circuit components 200 so as to remove particles on top surfaces of the first conductors 140, the first dielectric layer 130, the second conductors 240 and the second dielectric layer 230. The first active surface AS1 of the photonic wafer W and the second active surfaces AS2 of the electric integrated circuit components 200 may be cleaned by wet cleaning, for example. Not only particles are removed, but also native oxide formed on the top surfaces of the first conductors 140 and the second conductors 240 may be removed. The native oxide formed on the top surfaces of the first conductors 140 and the second conductors 240 may be removed by chemicals used in the wet cleaning, for example.

After cleaning the first active surface AS1 of the photonic wafer W and the second active surfaces AS2 of the electric integrated circuit components 200, activation of the top surfaces of the first dielectric layer 130 and the second dielectric layer 230 may be performed for development of high bonding strength. In some embodiments, plasma activation may be performed to treat the top surfaces of the first dielectric layer 130 and the second dielectric layer 230.

When the activated top surface of the first dielectric layer 130 is in contact with the activated top surface of the second dielectric layer 230, the first dielectric layer 130 of the photonic wafer W and the second dielectric layers 230 of the electric integrated circuit components 200 are pre-bonded. In other words, the photonic wafer W and the electric integrated circuit components 200 are pre-bonded through the pre-bonding of the first dielectric layer 130 and the second dielectric layer 230. After the first dielectric layer 130 and the second dielectric layer 230 are pre-bonded, the first conductors 140 are in contact with and electrically connected to the second conductors 240.

After pre-bonding the electric integrated circuit components 200 onto the photonic wafer W, bonding of the electric integrated circuit components 200 and the photonic wafer W is performed. The bonding of the electric integrated circuit components 200 and the photonic wafer W may include a treatment for dielectric-to-dielectric bonding and a thermal annealing for conductor-to-conductor bonding. In some embodiments, the treatment for dielectric-to-dielectric bonding is performed to strengthen the bonding between the first dielectric layer 130 and the second dielectric layer 230. For example, the treatment for dielectric-to-dielectric bonding may be performed at temperature ranging from about 100 Celsius degree to about 150 Celsius degree. After performing the treatment for dielectric-to-dielectric bonding, the thermal annealing for conductor-to-conductor bonding is performed to facilitate the bonding between the first conductors 140 and the second conductors 240. For example, the thermal annealing for conductor-to-conductor bonding may be performed at temperature ranging from about 300 Celsius degree to about 400 Celsius degree. The process temperature of the thermal annealing for conductor-to-conductor bonding is higher than that of the treatment for dielectric-to-dielectric bonding. After performing the thermal annealing for conductor-to-conductor bonding, the first dielectric layer 130 is bonded to the second dielectric layer 230 and the first conductors 140 are bonded to the second conductors 240. In some embodiments, the first conductors 140 may be conductive vias (e.g., copper vias), conductive pads (e.g., copper pads) or the combinations thereof while the second conductors 240 may be conductive vias (e.g., copper vias), conductive pads (e.g., copper pads) or the combinations thereof. For example, the conductor-to-conductor bonding between the first conductors 140 and the second conductors 240 may be via-to-via bonding, pad-to-pad bonding or via-to-pad bonding.

After performing the bonding of the electric integrated circuit component 200 and the photonic wafer W, the first interconnection structure 120 and the second interconnection structure 220 are electrically connected to each other through the first conductors 140 and the second conductors 240.

Although in FIG. 1B, the electric integrated circuit component 200 is bonded to the photonic wafer W, the disclosure is not limited thereto. In some alternative embodiments, the electric integrated circuit component 200 may be bonded to the photonic wafer W through a flip-chip packaging technique. In such embodiments, the electric integrated circuit component 200 may be bonded to the photonic wafer W through the solder joints.

Referring to FIG. 1C, after bonding the electric integrated circuit components 200 to the photonic wafer W, an insulating material 300 is formed to cover the photonic wafer W and encapsulate the electric integrated circuit components 200. The maximum thickness of the insulating material 300 may be greater than the thickness of the electric integrated circuit components 200. That is, as shown in FIG. 1C, the electric integrated circuit components 200 are buried by the insulating material 300. In some embodiments, the insulating material 300 may be conformally formed by chemical vapor deposition (CVD), or other suitable deposition processes.

In some embodiment, as shown in FIG. 1C, the insulating material 300 may be a single-layered structure and the material of the insulating material 300 may include silicon oxide, silicon nitride, and/or tetraethoxysilane (TEOS). However, the disclosure is not limited thereto. In some alternative embodiments, the insulating material 300 may be a multi-layered structure and include a plurality of stacked dielectric layers. Furthermore, the stacked dielectric layers may be formed from multiple layers of alternating dielectric materials (e.g., alternating silicon oxide/silicon nitride layers), and the multiple layers of alternating dielectric materials mat have the same thickness or varying thicknesses.

Referring to FIG. 1D, a grinding or polishing process is performed on the insulating material 300 so as to partially remove the insulating material 300 until the rear surfaces RS2 of the electric integrated circuit components 200 are exposed. In some embodiments, the insulating material 300 may be partially removed by a chemical mechanical polishing (CMP) process, a mechanical grinding process, the combination thereof or other suitable removal processes. After performing the grinding or polishing process, an insulating encapsulant 300′ is formed and the optical input/output portions 100b of the photonic integrated circuit components 100 are covered by the insulating encapsulant 300′. As shown in FIG. 1D, each of the electric integrated circuit components 200 is laterally encapsulated by the insulating encapsulant 300′. Furthermore, the insulating encapsulant 300′ physically contacts the sidewalls of the electric integrated circuit components 200. As shown in FIG. 1D, the illustrated top surface of the insulating encapsulant 300′ is substantially flush or coplanar with the rear surfaces RS2 of the electric integrated circuit components 200.

In some embodiments, as shown in FIG. 1D, the insulating encapsulant 300′ may be a single-layered structure and the material of the insulating encapsulant 300′ may include silicon oxide, silicon nitride, and/or tetraethoxysilane (TEOS). However, the disclosure is not limited thereto. In some alternative embodiments, the insulating encapsulant 300′ may be a multi-layered structure and include a plurality of stacked dielectric layers. Furthermore, the stacked dielectric layers may be formed from multiple layers of alternating dielectric materials (e.g., alternating silicon oxide/silicon nitride layers), and the multiple layers of alternating dielectric materials mat have the same thickness or varying thicknesses.

Referring to FIG. 1E, after forming the insulating encapsulant 300′, a support layer 310 is formed on the illustrated top surface of the insulating encapsulant 300′ and the rear surfaces RS2 of the electric integrated circuit components 200. In some embodiments, the material of the support layer 310 includes silicon, SiN, and/or SiO₂. In some embodiments, the support layer 310 is formed by dielectric-dielectric bonding, metal-to-metal bonding, silicon-to-dielectric bonding, silicon-to-silicon bonding, wafer-to-wafer bonding, or other suitable deposition processes.

Referring to FIG. 1E and FIG. 1F, a rear side grinding or polishing process is performed on the first rear surface RS1 of the photonic wafer W until the through semiconductor vias 112 are exposed at the first rear surface RS1. In some embodiments, the photonic wafer W may be thinned by a chemical mechanical polishing (CMP) process, a mechanical grinding process, the combination thereof or other suitable removal processes. Then, a plurality of conductive terminals 400 electrically connected to the through semiconductor vias 112 are formed on the first rear surface RS1 of the photonic wafer W. In some embodiments, the conductive terminals 400 are, for example, solder balls, metal pillars, controlled collapse chip connection (C4) bumps, micro bumps, electroless nickel-electroless palladium-immersion gold (ENEPIG) formed bumps or the like.

Referring to FIG. 1F and FIG. 1G, after forming the conductive terminals 400, a singulation process is performed along the scribe lines SL such that a plurality of singulated optical engines OE are formed. As illustrated in FIG. 1F and FIG. 1G, the formation of the conductive terminals 400 is performed before the singulation process for forming the singulated optical engines OE, however, the invention is not limited thereto. In some alternative embodiments, the formation of the conductive terminals 400 may be performed after the singulation process.

As shown in FIG. 1G, the optical engine OE includes the photonic integrated circuit component 100, the electric integrated circuit component 200, the insulating encapsulant 300′ and the support layer 310. The photonic integrated circuit component 100 includes the electrical bonding portion 100a and at least one optical input/output portion 100b configured to transmit and receive the optical signal. The electric integrated circuit component 200 is disposed on the electrical bonding portion 100a of the photonic integrated circuit component 100 and is electrically connected to the photonic integrated circuit component 100. For example, the electric integrated circuit component 200 is bonded with the photonic integrated circuit component 100. The electric integrated circuit component 200 is laterally encapsulated by and embedded in the insulating encapsulant 300′. For example, the insulating encapsulant 300′ physically contacts sidewalls of the electric integrated circuit component 200.

Further, as shown in FIG. 1G, in the optical engine OE, the photonic integrated circuit component 100 is disposed between the conductive terminals 400 and the electric integrated circuit component 200. In detail, the conductive terminals 400 are disposed near the first rear surface RS1. However, the disclosure is not limited thereto. In some alternative embodiments, the electric integrated circuit component 200 is disposed between the conductive terminals 400 and the photonic integrated circuit component 100. In such embodiments, the conductive terminals 400 may be disposed near the rear surface RS2 of the electric integrated circuit component 200.

Referring to FIG. 1H, a lens 500 is formed on the sidewall of the optical engine OE. In detail, the lens 500 is formed on and directly in contact with the sidewall of the photonic integrated circuit component 100 to be aligned with the optical input/output portion 100b of the photonic integrated circuit component 100. That is, no gap is formed between the lens 500 and the photonic integrated circuit component 100. The lens 500 is utilized to guide the optical signal (e.g., light) to the optical input/output portion 100b of the photonic integrated circuit component 100 and acts as a focusing member. The lens 500 is formed by a three-dimensional (3D) printing process. As shown in FIG. 1H, the lens 500 is directly printed on the sidewall of the photonic integrated circuit component 100 by a 3D printing process. That is, the lens 500 is secured on the sidewall of the photonic integrated circuit component 100. As such, the alignment relationship between the photonic integrated circuit component 100 and the lens 500 is set due to securing the lens 500 on the optical input/output portion 100b. In some embodiments, a three dimensional printing apparatus is used for forming the printing material on the optical engine OE. In detail, the printing material is printed at a predetermined location by the three dimensional printing apparatus so as to form the lens 500 on the sidewall of the photonic integrated circuit component 100 as shown in FIG. 1H.

In some embodiments, the lens 500 is micro-lens. The lens 500 includes any suitable material (e.g., silicon, glass, polymer, etc.), and the refractive index of the lens 500 ranges from about 1 to about 3.5. In some embodiments, a silicon lens having the higher refractive index (about 3.5) is used as the lens 500. The lens 500 may have a predetermined focal length that is capable of focusing light into the optical input/output portion 100b of the photonic integrated circuit component 100. The thickness T1 of the lens 500 may range from about 1 μm to about 100 μm depending on the predetermined focal length. In some embodiments, the lens 500 is a bulk silicon substrate having the thickness T1 being from about 20 μm to about 100 μm. In some embodiments, the diameter D1 of the lens 500 may range from about 1 μm to about 100 μm. In some embodiments, the lens 500 is a bulk silicon substrate having the diameter D1 being from about 20 μm to about 100 μm.

Still referring to FIG. 1H, in some embodiments, the alignment between the lens 500 and the optical input/output portion 100b of the photonic integrated circuit component 100 is checked by using an optical signal port 510. In some embodiments, the optical signal port 510 is an optical input/output (I/O) port where optical signals may enter and/or exit. As shown in FIG. 1H and FIG. 2, the optical signal port 510 includes a plurality of fibers 511, a fiber mesa 512, and optical components 513 and 514. In some embodiments, the fibers 511 are arranged in a parallel manner to form a fiber array module. For example, the fiber 511 may be a lensed fiber in which a lens shape for an optical connection is formed at a tip portion facing the optical component 513. In some embodiments, the fiber mesa 512 is configured to abut against the fibers 511 to support or secure the fibers 511. Alternatively, the fiber mesa 512 is omitted. In some embodiments, as shown in FIG. 1H, the optical component 513 is a lens that is capable of focusing the optical signal (e.g., light) onto the optical component 514, and the optical component 514 is a reflector that is able to turning and/or refracting the path of the optical signal. In detail, a reflective surface of the optical component 514 faces downwardly toward the lens 500, as shown in FIG. 1H.

In some embodiments, the fibers 511 are optically coupled to the optical input/output portion 100b of the photonic integrated circuit component 100 through the optical components 513 and 514 and the lens 500. As such, the optical signal port 510 is used to check the alignment between the lens 500 and the optical input/output portion 100b of the photonic integrated circuit component 100. In detail, as shown in FIG. 1H, an optical beam OP1 emitted from the fibers 511 enters the optical component 513, is reflected by the optical component 514, exits the optical signal port 510, and travels toward and enters the lens 500. The optical component 513 acting as the focusing member focus the input beam onto the optical component 514. Also, the lens 500 focus the incident beam as it exits the optical signal port 510 and before it couples to the photonic integrated circuit component 100.

Still referring to FIG. 1H, in some embodiments, the optical signal port 510 leans against the socket 520. The socket 520 has limiting portions 522. The limiting portions 522 are formed on top of the socket 520 and are used as a guide structure for an overlying component (i.e., the optical signal port 510). In some embodiments, each of the limiting portions 522 is a staggered structure on the top side of the socket 520 to provide an interfering structure for the optical signal port 510. As shown in FIG. 1H, the optical signal port 510 stacks on the socket 520 and has limiting portions 515 that are a structure corresponding to the limiting portions 522 of the socket 520. Specifically, the limiting portions 515 of the optical signal port 510 are structurally interfered with the limiting portions 522 of the socket 520, so that the optical signal port 510 is removable from the socket 520. In order to avoid the optical signal port 510 being damaged in the subsequent processing step, the optical signal port 510 can be detached from the socket 522 in advance (as shown in FIG. 1I). Also, in the case that the optical signal port 510 is failed, the optical signal port 510 can be detached from the socket 522 and another optical signal port 510 can be provided to replace the failed one without damaging the lens 500 or any component of the optical engine OE.

The limiting portion 522 of the socket 520 in FIG. 1H is a protrusion while the limiting portion 515 of the optical signal port 510 is a recess, but the disclosure is not limited thereto. In alternative embodiments, the limiting portion 522 of the socket 520 is a recess and the limiting portion 515 of the optical signal port 510 is a protrusion complementary to the recess constructed by the limiting portion 522. The number of the limiting portions 522 and the number of the limiting portions 515 are not limited in the disclosure, and may be more than or less than what is depicted in FIG. 1H, and may be designated based on demand and/or design layout.

Referring to FIG. 1I, after the alignment between the lens 500 and the optical input/output portion 100b is checked, an adhesive layer 530 is formed between the socket 520 and the optical engine OE to provide mechanical fixation. As such, the optical signal port 510 is positioned at the position and orientation where the optical signal port 510 is capable of being optically communicated with the photonic integrated circuit component 100. In detail, the socket 520 is attached onto the support layer 310 of the optical engine OE through the adhesive layer 530. In some embodiments, the adhesive layer 530 is difficultly removed from the optical engine OE so that the socket 520 can be substantially permanently attached on the optical engine OE. Subsequently, after forming the adhesive layer 530, the optical signal port 510 is detached from the socket 522.

Referring to FIG. 1J, after the optical signal port 510 is detached from the socket 522 attached onto the optical engine OE, the optical engine OE is mounted on a circuit substrate 600. In some embodiments, a reflow process is performed to bond the conductive terminals 400 of the optical engine OE to the circuit substrate 600. Other suitable mounting techniques may be used. In some embodiments, as shown in FIG. 1J, the circuit substrate 600 includes a substrate 602 and conductive vias 604 extending through the substrate 602. In some embodiments, the conductive terminals 400 of the optical engine OE are electrically connected to the conductive vias 604 of the circuit substrate 600. For example, the conductive terminals 400 of the optical engine OE are directly in contact with the conductive vias 604 of the circuit substrate 600 to render electrical connection. In some embodiments, an underfill UF1 is optionally formed on the circuit substrate 600 to laterally around the conductive terminals 400. In some embodiments, the underfill UF1 may be utilized to protect the conductive terminals 400.

Still referring to FIG. 1J, in some embodiments, the circuit substrate 600 is bonded and attached to a package structure 700 by using a plurality of conductive terminals 610. In some embodiments, before bonding the circuit substrate 600 to the package structure 700, the conductive terminals 610 may be formed on the circuit substrate 600 opposite to the optical engine OE. In some embodiments, a reflow process is performed to bond the conductive terminals 610 to the package structure 700. Other suitable mounting techniques may be used. In some embodiments, the conductive terminals 610 are, for example, solder balls, metal pillars, controlled collapse chip connection (C4) bumps, micro bumps, electroless nickel-electroless palladium-immersion gold (ENEPIG) formed bumps or the like. In some embodiments, the package structure 700 is a multi-chip module (MCM) package, although it should be appreciated that embodiments may be applied to other 3DIC packages. In some embodiments, an underfill UF2 is optionally formed on the package structure 700 to laterally around the conductive terminals 610. In some embodiments, the underfill UF2 may be utilized to protect the conductive terminals 610.

Still referring to FIG. 1J, in some embodiments, a plurality of conductive terminals 702 are formed on the package structure 700 opposite to the circuit substrate 600. In some embodiments, the conductive terminals 702 are solder balls, ball grid array (BGA) balls, or the like. In some embodiments, the conductive terminals 702 are made of a conductive material with low resistivity, such as Sn, Pb, Ag, Cu, Ni, Bi, or an alloy thereof.

Referring to FIG. 1K, after the optical engine OE is mounted on a circuit substrate 600, the optical signal port 510 is re-attached onto the socket 520 to form the package assembly 10. That is, in the package assembly 10, the optical signal port 510 is connected to the optical engine OE via the socket 520. As shown in FIG. 1K, in the package assembly 10, the 3D printed lens 500 is disposed on the sidewall of the photonic integrated circuit component 100 and disposed between the photonic integrated circuit component 100 and the optical signal port 510 to guide and focus the optical signal (e.g., light) from the optical signal port 510 to the optical input/output portion 100b, so that the utilization ratio of the optical signal from the optical signal port 510 is improved. Further, as shown in FIG. 1K, in the package assembly 10, the 3D printed lens 500 is directly in contact with the sidewall of the photonic integrated circuit component 100, thereby the 3D printed lens 500 is secured on the sidewall of the photonic integrated circuit component 100. As such, the alignment relationship between the photonic integrated circuit component 100 and the lens 500 can be set, and even when the misalignment between the lens 500 and the optical signal port 510 occurs, the optical signal (e.g., light) from the optical signal port 510 still can be guided to the optical input/output portion 100b via the lens 500. In view of this, by arranging the 3D printed lens 500 being directly in contact with and secured on the sidewall of the photonic integrated circuit component 100, the coupling tolerance of the lens 500 and the optical input/output portion 100b is improved. In some embodiments, the coupling tolerance of the lens 500 and the optical input/output portion 100b is improved by at least about 2 μm. From another point of view, the alignment between the lens 500 and the optical signal port 510 is used a passive alignment way. In addition, since the 3D printed lens 500 is directly in contact with the sidewall of the photonic integrated circuit component 100, there is no gap between the lens 500 and the photonic integrated circuit component 100, which enhances the space utilization and reduces the size of the package assembly 10.

As shown in FIGS. 1A through 1K, the 3D printed lens 500 is formed after the singulation process is performed to form the singulated optical engines OE. However, the invention is not limited thereto. In some alternative embodiments, the 3D printed lens 500 can be formed during the singulation process. In such embodiments, the singulation process includes performing a laser grooving process, and then performing a wafer sawing process to form the singulated optical engines OE. And, the 3D printed lens 500 is formed on the photonic integrated circuit component 100 after performing the laser grooving process and before performing the wafer sawing process.

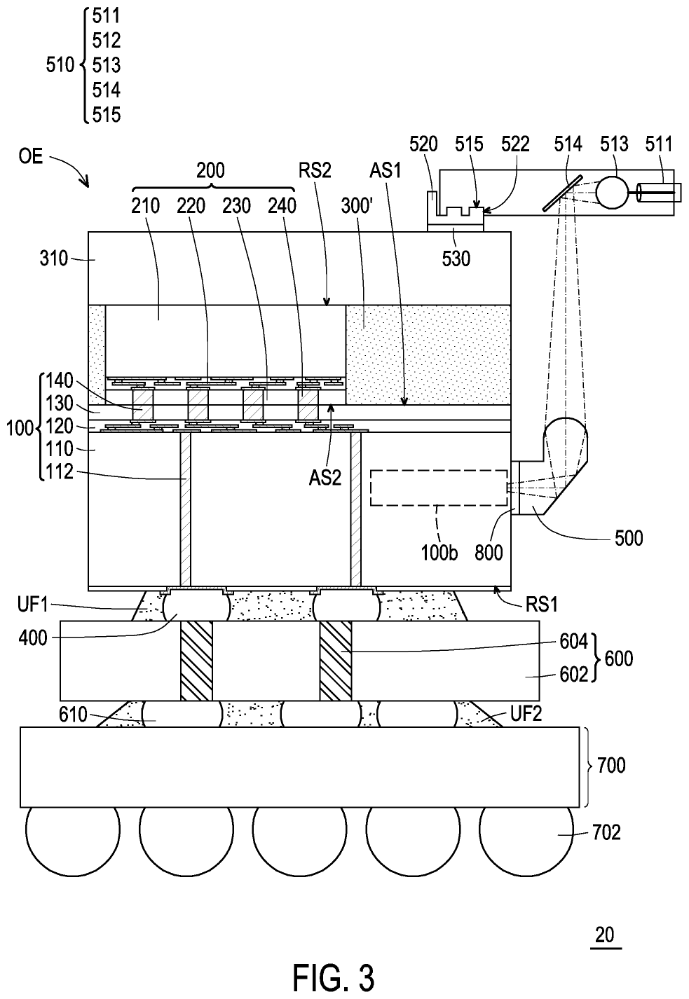

FIG. 3 is a schematic cross-sectional view of a package assembly 20 in accordance with some alternative embodiments of the present disclosure. The package assembly 20 of FIG. 3 is similar to the package assembly 10 of FIG. 1K, hence the same reference numerals are used to refer to the same or liked parts, and its detailed description will be omitted herein. Referring to FIG. 3 and FIG. 1K, the difference between them lies in that, the semiconductor assembly 20 further includes an adhesive layer 800 between the lens 500 and the photonic integrated circuit component 100. In detail, the 3D printed lens 500 is attached on the sidewall of the photonic integrated circuit component 100 via the adhesive layer 800.

The adhesive layer 800 is configured to provide optical transparency and mechanical fixation. As such, the lens 500 is secured on the sidewall of the photonic integrated circuit component 100 via the adhesive layer 800. In some embodiments, the adhesive layer 800 includes clear (or transparent) adhesive material or other suitable optical glue/grease. In some embodiments, the adhesive layer 800 is a layer of index-matching adhesive material. For example, the adhesive layer 800 is index-matched to the lens 500 and to the sidewall of the photonic integrated circuit component 100 that the lens 500 attached to reduce optical loss. The refractive index and the thickness of the adhesive layer 800 may be adjusted according to the refractive indices of the lens 500 and the photonic integrated circuit component 100. The adhesive layer 800 may be a single-layer or multi-layer structure. The material of the adhesive layer 800 may include an epoxy based compound, a silicone based compound, an acrylic based compound, a combination thereof, or the like.

As shown in FIG. 3, in the package assembly 20, the 3D printed lens 500 is disposed on and attached onto the sidewall of the photonic integrated circuit component 100 and disposed between the photonic integrated circuit component 100 and the optical signal port 510 to guide and focus the optical signal (e.g., light) from the optical signal port 510 to the optical input/output portion 100b, so that the utilization ratio of the optical signal from the optical signal port 510 is improved. Further, as shown in FIG. 3, in the package assembly 20, the 3D printed lens 500 is attached to the sidewall of the photonic integrated circuit component 100 via the adhesive layer 800, thereby the 3D printed lens 500 is secured on the sidewall of the photonic integrated circuit component 100. As such, the alignment relationship between the photonic integrated circuit component 100 and the lens 500 can be set, and even when the misalignment between the lens 500 and the optical signal port 510 occurs, the optical signal (e.g., light) from the optical signal port 510 still can be guided to the optical input/output portion 100b via the lens 500. In view of this, by arranging the 3D printed lens 500 being secured on the sidewall of the photonic integrated circuit component 100, the coupling tolerance of the lens 500 and the optical input/output portion 100b is improved. In some embodiments, the coupling tolerance of the lens 500 and the optical input/output portion 100b is improved by at least about 2 μm. In addition, in the package assembly 20, the 3D printed lens 500 is secured on the sidewall of the photonic integrated circuit component 100 via the adhesive layer 800, which enhances the space utilization and reduces the size of the package assembly 20.

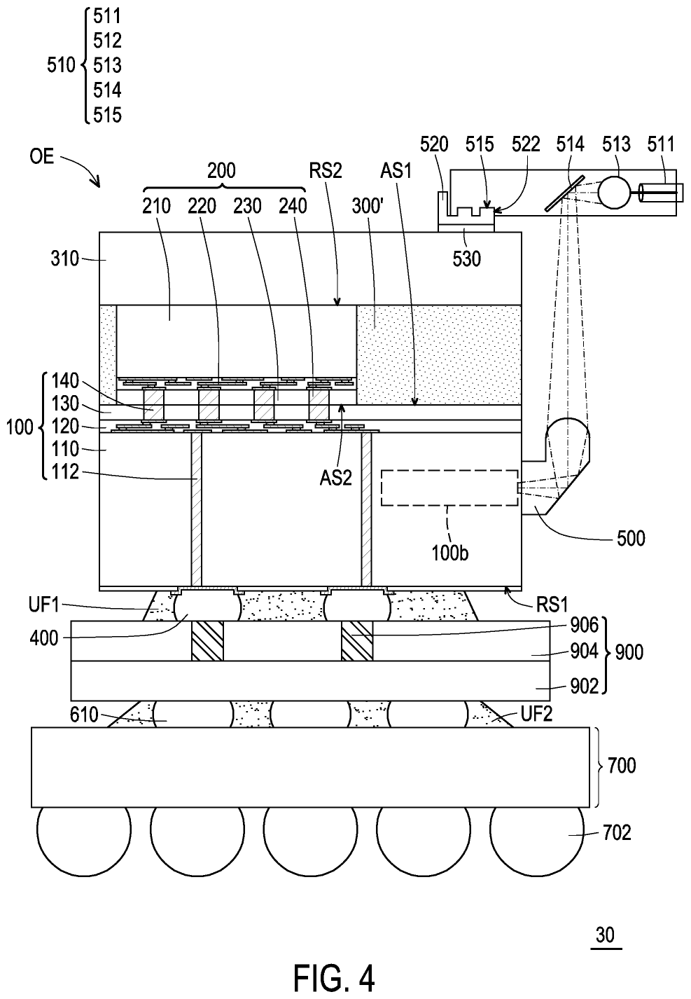

FIG. 4 is a schematic cross-sectional view of a package assembly 30 in accordance with some alternative embodiments of the present disclosure. The package assembly 30 of FIG. 4 is similar to the package assembly 10 of FIG. 1K, hence the same reference numerals are used to refer to the same or liked parts, and its detailed description will be omitted herein. Referring to FIG. 4 and FIG. 1K, the difference between them lies in that, in the semiconductor assembly 30, the optical engine OE is mounted on an interposer 900.

In some embodiments, the interposer 900 is referred to an “inorganic interposer”. In some embodiments, as shown in FIG. 4, the interposer 900 includes a substrate 902, a dielectric layer 904 over the substrate 902, and conductive features 906 laterally surrounded by the dielectric layer 904. In some embodiments, the conductive features 906 include conductive pads. However, the invention is not limited thereto. In some alternative embodiments, the conductive features 906 include a combination of conductive lines and conductive vias. In some embodiments, the conductive terminals 400 of the optical engine OE are electrically connected to the conductive features 906 of the interposer 900. For example, the conductive terminals 400 of the optical engine OE are directly in contact with the conductive features 906 of the interposer 900 to render electrical connection. In some embodiments, the interposer 900 is bonded and attached to the package structure 700 by using the conductive terminals 610. In some embodiments, the package assembly 30 illustrated in FIG. 4 may be referred to as a “CoWoS (Chip on Wafer on Substrate) package.” As illustrated in FIG. 4, the interposer 900 is sandwiched or interposed between the optical engine OE and the package structure 700.

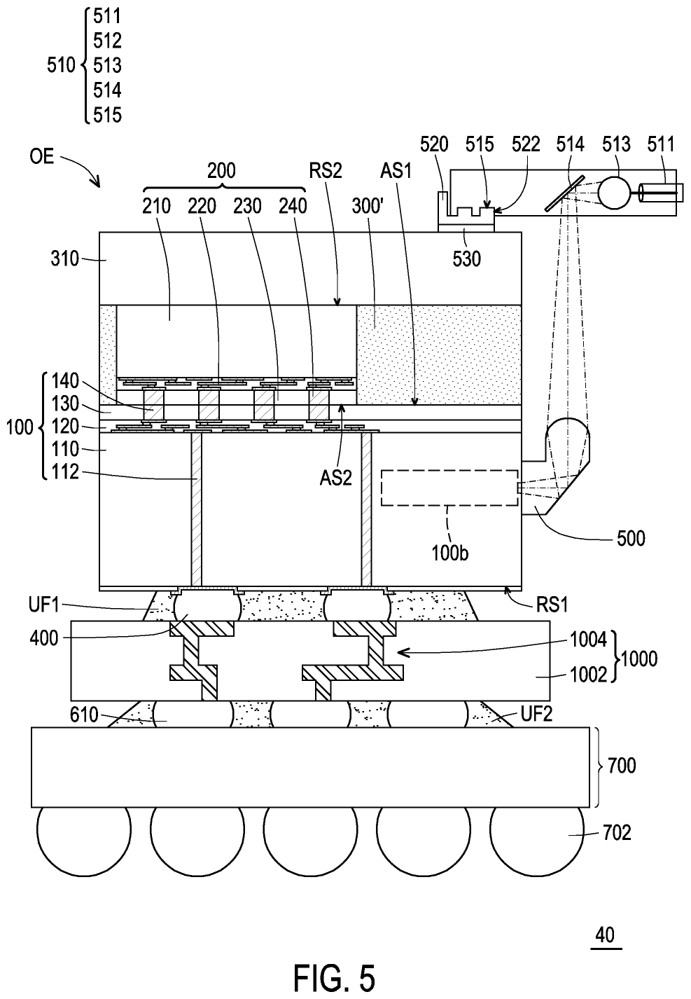

FIG. 5 is a schematic cross-sectional view of a package assembly 40 in accordance with some alternative embodiments of the present disclosure. The package assembly 40 of FIG. 5 is similar to the package assembly 10 of FIG. 1K, hence the same reference numerals are used to refer to the same or liked parts, and its detailed description will be omitted herein. Referring to FIG. 5 and FIG. 1K, the difference between them lies in that, in the semiconductor assembly 40, the optical engine OE is mounted on an interposer 1000.

In some embodiments, the interposer 1000 is referred to an “organic interposer”. The organic interposer is beneficial to reduce the total process cost of the package assembly 40 since the organic interposer is a low-cost interposer. In some embodiments, as shown in FIG. 5, the interposer 1000 includes at least one dielectric layer 1002 and conductive features 1004 in the dielectric layer 1002. In some embodiments, the conductive features 1004 may comprise pads, vias and/or trace lines. For simplicity, the dielectric layer 1002 is illustrated as a bulky layer in FIG. 5, but it should be understood that the dielectric layer 1002 may be constituted by multiple dielectric layers. In some embodiments, the conductive terminals 400 of the optical engine OE are electrically connected to the conductive features 1004 of the interposer 1000. For example, the conductive terminals 400 of the optical engine OE are directly in contact with the conductive features 1004 of the interposer 1000 to render electrical connection. In some embodiments, the interposer 1000 is bonded and attached to the package structure 700 by using the conductive terminals 610, and the conductive terminals 610 are electrically connected to the conductive features 1004 of the interposer 1000.

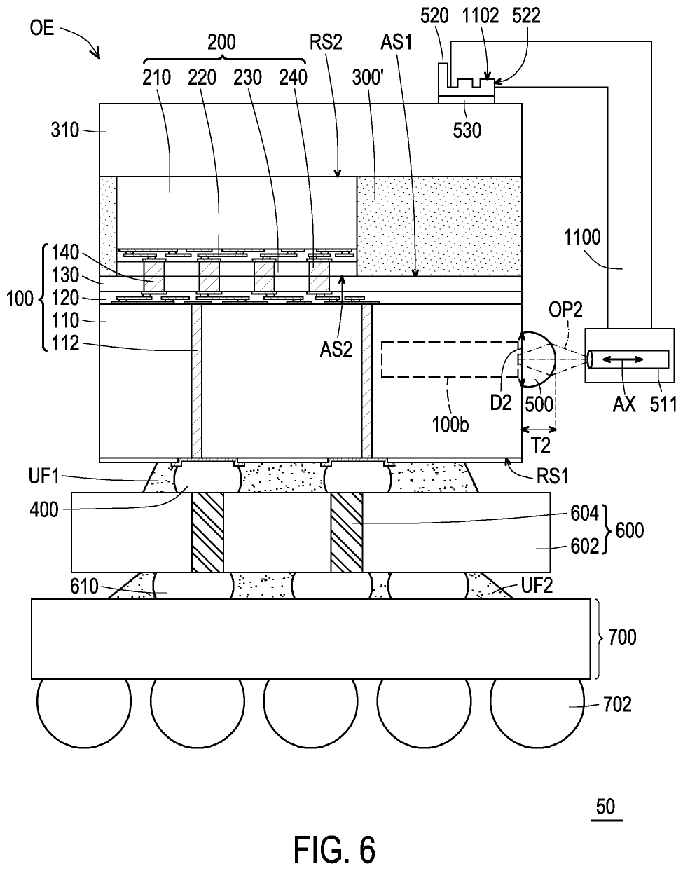

It is noted that the lens 500 may have a variety of shapes and sizes depending on a refractive index of the material used for the lens and/or a configuration relationship between the lens 500 and the optical signal port 510. Other configuration of the package assembly will be discussed below in conjunction with FIG. 6.

FIG. 6 is a schematic cross-sectional view of a package assembly 50 in accordance with some alternative embodiments of the present disclosure. The package assembly 50 of FIG. 6 is similar to the package assembly 10 of FIG. 1K, hence the same reference numerals are used to refer to the same or liked parts, and its detailed description will be omitted herein. The differences between the package assembly 50 and the package assembly 10 will be described below.

Referring to FIG. 6, in the package assembly 50, the fibers 511 of the optical signal port 510 face the sidewall of the photonic integrated circuit component 100 that the lens 500 is disposed on. For example, the fiber 511 may be a lensed fiber in which a lens shape for an optical connection is formed at a tip portion facing the lens 500 and the sidewall of the photonic integrated circuit component 100 that the lens 500 is disposed on.

From another point of view, in the package assembly 50, the fibers 511 of the optical signal port 510 are laterally aligned with the lens 500 and the optical input/output portion 100b of the photonic integrated circuit component 100 to provide the optical signals. In some embodiments, the fiber axis AX may be substantially parallel to a normal direction of the sidewall of the photonic integrated circuit component 100 that the lens 500 is disposed on. In some embodiments, an angle (e.g., between a few degrees to about 90 degrees) may be formed between the fiber axis AX and the sidewall of the photonic integrated circuit component 100 that the lens 500 is disposed on. The angle between the fiber axis AX and the sidewall of the photonic integrated circuit component 100 that the lens 500 is disposed on may be adjusted depending on the characteristics of the fiber 511 and depending on how well the optical connection is optimized. It is noted that the angle between the fiber axis AX and the sidewall of the photonic integrated circuit component 100 that the lens 500 is disposed on construe no limitation in the disclosure. In some embodiments, in the package assembly 50, the thickness T2 of the lens 500 may range from about 1 μm to about 100 μm depending on the predetermined focal length. In some embodiments, in the package assembly 50, the diameter D2 of the lens 500 may range from about 1 μm to about 50 μm.

Further, in some embodiments, in the package assembly 50, the fibers 511 are optically coupled to the optical input/output portion 100b of the photonic integrated circuit component 100 through the lens 500. In detail, as shown in FIG. 6, an optical beam OP2 emitted from the fibers 511 enters the lens 500. The lens 500 focus the incident beam as it exits the optical signal port 510 and before it couples to the photonic integrated circuit component 100.

In some embodiments, a connection component 1100 is configured to be in contact with the optical signal port 510 to secure the optical signal port 510 onto the optical engine OE. In detail, as shown in FIG. 6, the connection component 1100 stacks on the socket 520 and has limiting portions 1102 that are a structure corresponding to the limiting portions 522 of the socket 520. Specifically, the limiting portions 1102 of the connection component 1100 are structurally interfered with the limiting portions 522 of the socket 520, so that the connection component 1100 is removable from the socket 520. That is, if need, the connection component 1100 can be detached from the socket 522.

The limiting portion 522 of the socket 520 in FIG. 6 is a protrusion while the limiting portion 1102 of the connection component 1100 is a recess, but the disclosure is not limited thereto. In alternative embodiments, the limiting portion 522 of the socket 520 is a recess and the limiting portion 1102 of the connection component 1100 is a protrusion complementary to the recess constructed by the limiting portion 522. The number of the limiting portions 522 and the number of the connection components 1100 are not limited in the disclosure, and may be more than or less than what is depicted in FIG. 6, and may be designated based on demand and/or design layout.

In some embodiments, the connection component 1100 and the optical signal port 510 are formed integrally. However, the disclosure is not limited thereto. In alternative embodiments, the optical signal port 510 is attached to the connection component 1100 via an adhesive layer (not shown).

As shown in FIG. 6, in the package assembly 50, the 3D printed lens 500 is disposed on the sidewall of the photonic integrated circuit component 100 and disposed between the photonic integrated circuit component 100 and the optical signal port 510 to guide and focus the optical signal (e.g., light) from the optical signal port 510 to the optical input/output portion 100b, so that the utilization ratio of the optical signal from the optical signal port 510 is improved. Further, as shown in FIG. 6, in the package assembly 50, the 3D printed lens 500 is directly in contact with the sidewall of the photonic integrated circuit component 100, thereby the 3D printed lens 500 is secured on the sidewall of the photonic integrated circuit component 100. As such, the alignment relationship between the photonic integrated circuit component 100 and the lens 500 can be set, and even when the misalignment between the lens 500 and the optical signal port 510 occurs, the optical signal (e.g., light) from the optical signal port 510 still can be guided to the optical input/output portion 100b via the lens 500. In view of this, by arranging the 3D printed lens 500 being directly in contact with and secured on the sidewall of the photonic integrated circuit component 100, the coupling tolerance of the lens 500 and the optical input/output portion 100b is improved. In some embodiments, the coupling tolerance of the lens 500 and the optical input/output portion 100b is improved by at least about 2 μm. In addition, since the 3D printed lens 500 is directly in contact with the sidewall of the photonic integrated circuit component 100, there is no gap between the lens 500 and the photonic integrated circuit component 100, which enhances the space utilization and reduces the size of the package assembly 10.

As shown in FIG. 6, in the package assembly 50, the optical engine OE is mounted on the circuit substrate 600, but the disclosure is not limited thereto. In alternative embodiments, the optical engine OE of the package assembly 50 may be mounted on the interposer 900 (as shown in FIG. 4), or on the interposer 1000 (as shown in FIG. 5). As shown in FIG. 6, in the package assembly 50, the 3D printed lens 500 is directly in contact with the sidewall of the photonic integrated circuit component 100, but the disclosure is not limited thereto. In alternative embodiments, the 3D printed lens 500 may be disposed on and secured on the sidewall of the photonic integrated circuit component 100 via the adhesive layer 800 (as shown in FIG. 3).

In accordance with an embodiment, a package assembly is provided. The package assembly includes a photonic integrated circuit component, an electric integrated circuit component, a lens and an optical signal port. The photonic integrated circuit component comprises an optical input/output portion configured to transmit and receive optical signal. The electric integrated circuit component is electrically connected to the photonic integrated circuit component. The lens is disposed on a sidewall of the photonic integrated circuit component. The optical signal port is optically coupled to the optical input/output portion.

In accordance with an embodiment, a package assembly is provided. The package assembly includes an optical engine, a lens and an optical signal port. The optical engine includes a photonic integrated circuit component, an electric integrated circuit component, an insulating encapsulant and a support layer. The photonic integrated circuit component comprises an optical input/output portion configured to transmit and receive optical signal. The electric integrated circuit component is electrically connected to the photonic integrated circuit component. The insulating encapsulant encapsulates the electric integrated circuit component. The support layer is disposed on the electric integrated circuit component and the insulating encapsulant. The lens is secured on a sidewall of the photonic integrated circuit component. The optical signal port is connected with the optical engine and optically coupled to the optical input/output portion through the lens.

In accordance with an embodiment, a manufacturing method of a package assembly is provided. The method includes providing an optical engine comprising: a photonic integrated circuit component comprising an optical input/output portion configured to transmit and receive optical signal; an electric integrated circuit component, electrically connected to the photonic integrated circuit component; an insulating encapsulant laterally surrounded the electric integrated circuit component; and a support layer disposed on the electric integrated circuit component and the insulating encapsulant; securing a lens on a sidewall of the photonic integrated circuit component; and attaching an optical signal port onto the optical engine.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package assembly, comprising:
a photonic integrated circuit component comprising an optical input/output portion configured to transmit and receive optical signal;
an electric integrated circuit component, electrically connected to the photonic integrated circuit component;
a lens disposed on a sidewall of the photonic integrated circuit component; and
an optical signal port optically coupled to the optical input/output portion.

2. The package assembly as claimed in claim 1, wherein the lens is directly in contact with the sidewall of the photonic integrated circuit component, and aligned with the optical input/output portion.

3. The package assembly as claimed in claim 1, wherein the lens is disposed on the sidewall of the photonic integrated circuit component via an adhesive layer, and aligned with the optical input/output portion.

4. The package assembly as claimed in claim 1, wherein the optical signal port comprises a fiber laterally aligned with the lens and the optical input/output portion.

5. The package assembly as claimed in claim 4, wherein the fiber is optically coupled to the optical input/output portion through the lens.

6. The package assembly as claimed in claim 1, wherein the optical signal port comprises:
an optical component with a reflective surface facing downwardly toward the lens; and
a fiber aligned with the reflective surface of the optical component.

7. The package assembly as claimed in claim 6, wherein the fiber is optically coupled to the optical input/output portion through the lens and the optical component.

8. A package assembly, comprising:
an optical engine comprising:
a photonic integrated circuit component comprising an optical input/output portion configured to transmit and receive optical signal;
an electric integrated circuit component, electrically connected to the photonic integrated circuit component;
an insulating encapsulant encapsulating the electric integrated circuit component; and
a support layer disposed on the electric integrated circuit component and the insulating encapsulant;
a lens secured on a sidewall of the photonic integrated circuit component; and
an optical signal port connected with the optical engine and optically coupled to the optical input/output portion through the lens.

9. The package assembly as claimed in claim 8, wherein the sidewall of the photonic integrated circuit component is substantially leveled with a sidewall of the insulating encapsulant.

10. The package assembly as claimed in claim 8, wherein the lens is directly in contact with the sidewall of the photonic integrated circuit component.

11. The package assembly as claimed in claim 8, wherein the lens is attached on the sidewall of the photonic integrated circuit component via an adhesive layer.

12. The package assembly as claimed in claim 8, further comprising a socket attached on the support layer.

13. The package assembly as claimed in claim 12, wherein the optical signal port is connected with the optical engine via the socket.

14. The package assembly as claimed in claim 13, further comprising a connection component connected between the optical signal port and the socket.

15. The package assembly as claimed in claim 8, wherein the optical signal port comprises a fiber facing the sidewall of the photonic integrated circuit component.

16. The package assembly as claimed in claim 8, wherein the optical signal port comprises:
an optical component with a reflective surface facing downwardly toward the lens; and
a fiber facing the reflective surface of the optical component.

17. A manufacturing method of a package assembly, comprising:
providing an optical engine comprising:
a photonic integrated circuit component comprising an optical input/output portion configured to transmit and receive optical signal;
an electric integrated circuit component, electrically connected to the photonic integrated circuit component;
an insulating encapsulant laterally surrounded the electric integrated circuit component; and
a support layer disposed on the electric integrated circuit component and the insulating encapsulant;
securing a lens on a sidewall of the photonic integrated circuit component; and
attaching an optical signal port onto the optical engine.

18. The manufacturing method as claimed in claim 17, wherein the step of securing a lens on a sidewall of the photonic integrated circuit component comprising forming the lens on the sidewall of the photonic integrated circuit component by a 3D printing process.

19. The manufacturing method as claimed in claim 17, wherein the step of securing a lens on a sidewall of the photonic integrated circuit component comprising:
forming the lens by a 3D printing process; and
attaching the lens on the sidewall of the photonic integrated circuit component via an adhesive layer.

20. The manufacturing method as claimed in claim 17, further comprising:
using the optical signal port to check an alignment between the lens and the optical input/output portion.
